(19) United States
(12) Patent Application Publication
(10) Pub. No.: US 2006/0091418 A1
(43) Pub. Date: May 4, 2006

(54) Side emitting LED device and method of fabrication

(76) Inventor: Tong Fatt Chew, Penang (MY)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 10/981,042

(22) Filed: Nov. 4, 2004

(51) Int. Cl. H01L 33/00

(52) U.S. Cl. 257/100

(57) ABSTRACT

In one embodiment, a light emitting diode (LED) device comprises an LED die for generating output light and an encapsulant sealing the LED die, the encapsulant comprising a conical structure extending away from the LED die and positioned above the LED die, wherein a profile of the conical structure causes a cone of light centered around an axis of symmetry of the LED die to experience total internal reflection.

### TECHNICAL FIELD

The present application is generally related to side emitting LED devices.

### BACKGROUND

At the present time, liquid crystal displays (LCDs) have become commonplace for computer systems, televisions, and various electronic systems. Liquid crystal displays operate using the birefringent characteristics of liquid crystals and the ability to orient liquid crystal material using an electric field. Specifically, liquid crystal material is disposed within a front and back polarizer. Each pixel of an LCD display controls the liquid crystal within the respective portion of the display to rotate the polarization of the light after application of the first polarizer. Depending upon the state of a respective pixel, the second polarizer will either filter the light having the rotated polarization or allow light to pass.

Cold compact fluorescent lamps (CCFLs) have traditionally been used for backlighting LCDs. FIG. 1 depicts conventional CCFL 100 for use in an LCD. As shown in FIG. 1, CCFL 100 is positioned at the edge of crystal layers 101. Beam divergence and the optical properties of light guide 102 enable light to pass through crystal layers 101 in a substantially uniform manner for smaller displays. However, when LCD screen sizes increase beyond fourteen inches to twenty inches or beyond (e.g., for wall mounted televisions), edge-lit CCFL-based LCDs experience difficulties achieving uniform illumination. In particular, the lengthening of the light path to the center of the LCD panel causes more light loss through light guide 102. Accordingly, the image quality at the center of larger edge-lit LCDs can be relatively low.

More recently, light emitting diodes (LEDs) have been incorporated within LCDs. FIG. 2 depicts LCD 200 using LEDs 201 for backlighting. LED dies (the discrete semiconductor elements generating the emitted light) emit beams in a highly directional manner. Specifically, the intensity of the emitted light is greatest at the axis of rotational symmetry and falls off relatively quickly as the angle from the axis increases. The high directionality of the emitted light from an LED die requires adaptations to achieve uniform lighting of an LCD. To achieve relatively uniform lighting, LEDs 201 include packaging adaptations to enable operation as “side emission” devices. LCD 200 is also adapted to include bottom reflector 202 between LEDs 201, transparent polymethyl methacrylate (PMMA) layer 203, and diffuser 204 to achieve substantially uniform illumination.

Typically, the side emission characteristics of LEDs 201 are achieved by using a shaped, transparent encapsulant structure. FIG. 3 depicts conventional packaging structure 300 for side emitting LEDs. Packaging structure 300 includes a relatively deep depression 301 at the axis of rotational symmetry. The curvature associated with depression 301 causes total internal reflection for a cone of light near the axis of rotational symmetry. In practice the slope of the depression required near the optical axis of symmetry for total internal reflection of light emitting from the LED is very steep and it is difficult to manufacture in high volume LED devices having such a depression. For ease of manufacturing, the steep depression near and at the optical axis of symmetry of the LED device is truncated and replaced with a surface with a small radius of curvature or a flat surface. Light entering this small surface will not be totally internally reflected. In another practice, the slope of the depression is reduced near the optical axis, resulting in some light being refracted and emitted from the surface of the depression and at an angle that is not substantially away from the optical axis of symmetry of the LED device, instead of being totally internally reflected. Furthermore, in practice, reflective material 401 is typically used to coat the depression to ensure that light is emitted through the sides of LED 400 as shown in FIG. 4.

Known side emission LEDs are associated with a number of problems. For example, the steep slope required near the optical axis of symmetry for total internal reflection produces a molding feature in the mold that is difficult to de-mold. Furthermore, the tip of the mold used to form the depression within the encapsulant material experiences wear during LED production. In another example, to avoid the formation of steep slope near the optical axis, a less steep slope is implemented. An additional manufacturing step is introduced to avoid light escaping from surface of depression through refraction by implementing a reflective material deposited on the depression. This material is subject to peeling or separation from the surface of the encapsulant. In yet another example, the steep slope near the optical axis of symmetry of a conventional LED device necessitates the reflection of light at a large angle of incidence to the internal surface of the LED at the depression (e.g. with reference to light rays 302 and 303 in FIG. 3), causing successive internal reflections and large transmission losses to occur within the package before light can exit the LED device.

### SUMMARY

Some representative embodiments are directed to an encapsulant design for a side-emitting LED device. The encapsulant design preferably incorporates a conical structure for positioning according to the axis of rotational symmetry of the LED. Additionally, the conical structure is preferably provided within a relatively small depression of the encapsulant structure. The conical structure of the encapsulant provides a profile such that the light extracted from the LED is directed out of the package at an angle that substantially departs from the axis of rotational symmetry. Specifically, the angle of incidence of beams within the conical structure is greater than the critical angle and, hence, beams within the conical structure experience total internal reflection. The beams are directed internally toward the other side of the conical structure and are emitted from the side of the encapsulant structure.

In one embodiment, a method of manufacturing an LED device involves suitably molding an encapsulant structure. Specifically, an LED die may be mounted within a lead frame or other suitable structure. The LED die is electrically coupled to leads of the lead frame. A metal or other suitable mold defining the encapsulant design is positioned above the LED die and frame. Injection molding or another suitable molding technique is then used to form the transparent encapsulant surrounding the LED die. The transparent encapsulant can be formed using resin epoxy and other appropriate materials. As defined by the mold, the encapsulant possesses the conical structure above the LED die and is positioned according to the axis of rotational symmetry. Due to the contour of the conical structure and the refractive index of the encapsulant material, beams emitted from the LED die that are incident against the surface of the conical structure experience total internal reflection.

### BRIEF DESCRIPTION OF THE DRAWINGS

FIG. 1 depicts a conventional liquid crystal display that uses a side illumination design.

FIG. 2 depicts a conventional liquid crystal display that uses a direct backlighting design.

FIG. 3 depicts a conventional encapsulant design for side emission LEDs.

FIG. 4 depicts another conventional encapsulant design for side emission LEDs.

FIG. 5 depicts an LED device according to one representative embodiment.

FIG. 6 depicts a ray tracing diagram of the LED device shown in FIG. 5.

FIG. 7 depicts several manufacturing steps for an LED device according to one representative embodiment.

FIG. 8 depicts an LCD device according to one representative embodiment.

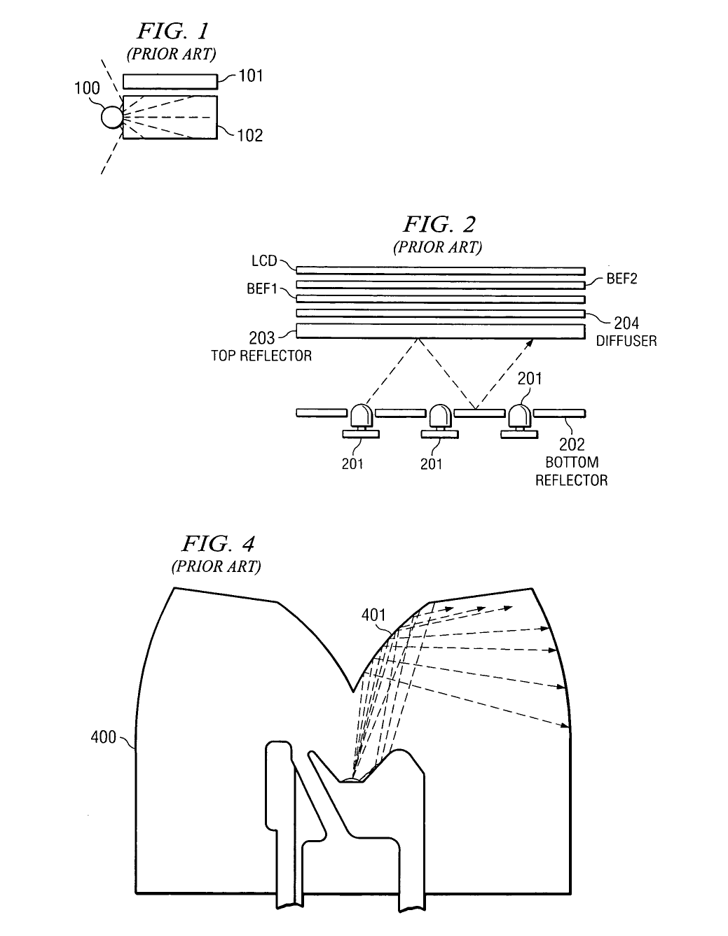

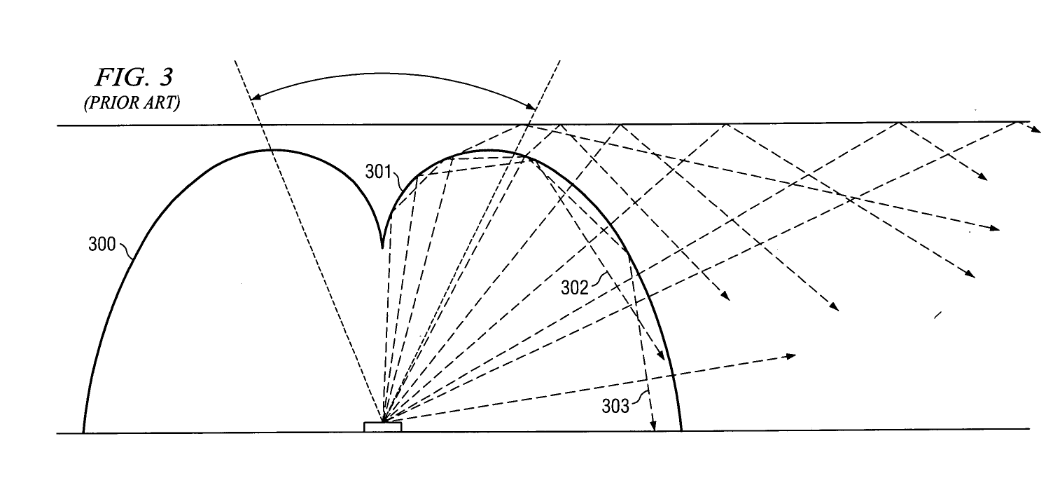

### DETAILED DESCRIPTION OF THE INVENTION

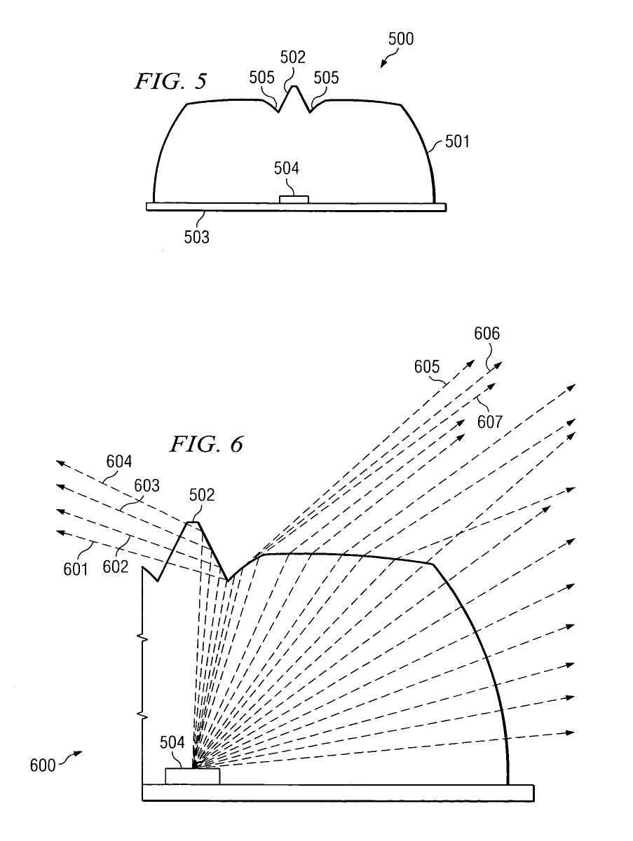

FIG. 5 depicts LED device 500 according to one representative embodiment. LED device 500 includes frame or printed circuit board 503 and LED die 504. LED die 504 is preferably hermetically sealed by encapsulant 501. Encapsulant 501 includes conical structure 502. Conical structure 502 is positioned above LED die 504 according to the axis of rotational symmetry associated with LED die 504. Conical structure 502 is disposed within a relatively small depression 505 of encapsulant 501.

FIG. 6 depicts ray tracing diagram 600 of LED device 500 according to one representative embodiment. Only the rays from the “right” half of LED device 500 are shown for the sake of clarity. As seen in FIG. 6, the angles between rays 601-604 and the axis of symmetry (defined by the normal vector extending from the middle of LED die 504) are relatively small. Rays 601-604 are incident with the surface of conical structure 502 and the angles of incidence are greater than the critical angle. Accordingly, rays 601-604 experience total internal reflection. Upon redirection, rays 601-604 exit encapsulant 501 on the opposite side of conical structure 502. Accordingly, the portion of the light emitted by LED die 504 that was originally directed toward the front of LED device 500 is emitted from the side of LED device 500.

Additionally, rays 605-607 are incident with the surface of encapsulant 501 immediately outside of conical structure and within depression 505. Due to depression 505 and the refractive index of encapsulant 501, rays 605-607 are redirected at the surface of encapsulant 501. Accordingly, depression 505 causes a greater range of angles to not experience direct emission of light from LED die 504.

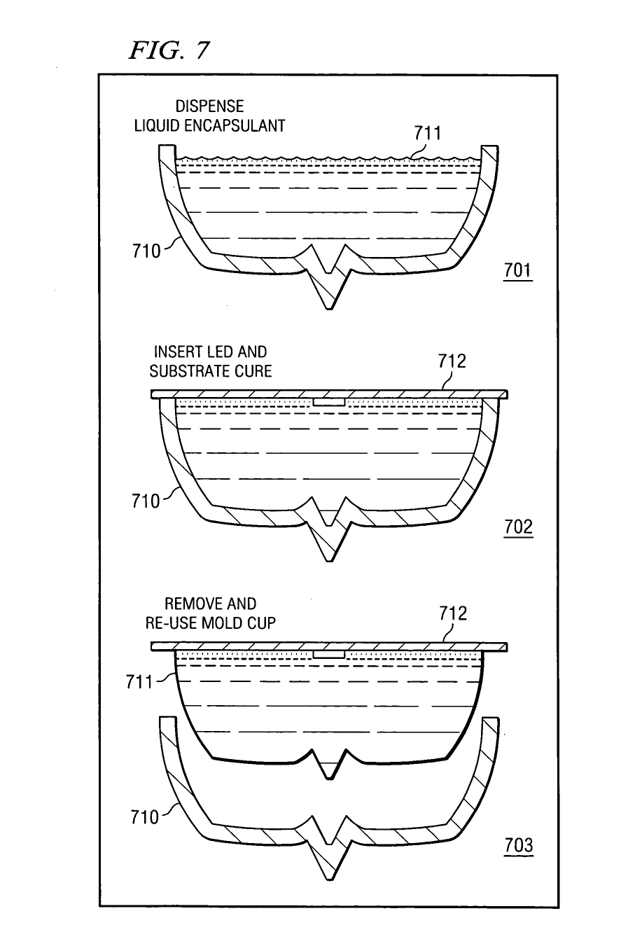

FIG. 7 depicts manufacturing steps 701 of an LED device according to one representative embodiment. In step 701, a mold is provided and liquid encapsulant material (e.g., resin epoxy) is dispensed within the mold. In step 702, frame or printed circuit board 712 including an LED die is inserted within the encapsulant material. The encapsulant material is then cured. In step 703, the LED device is removed from the mold cup which can then be reused in the manufacture of another LED device. In one alternative embodiment, the mold cup may form a integral part of the final LED device. In another alternative embodiment, the frame and LED die are positioned within a suitable mold and injection molding, transfer molding, or other suitable techniques are applied in lieu of dispensing the liquid encapsulant before placement of the frame and LED die.

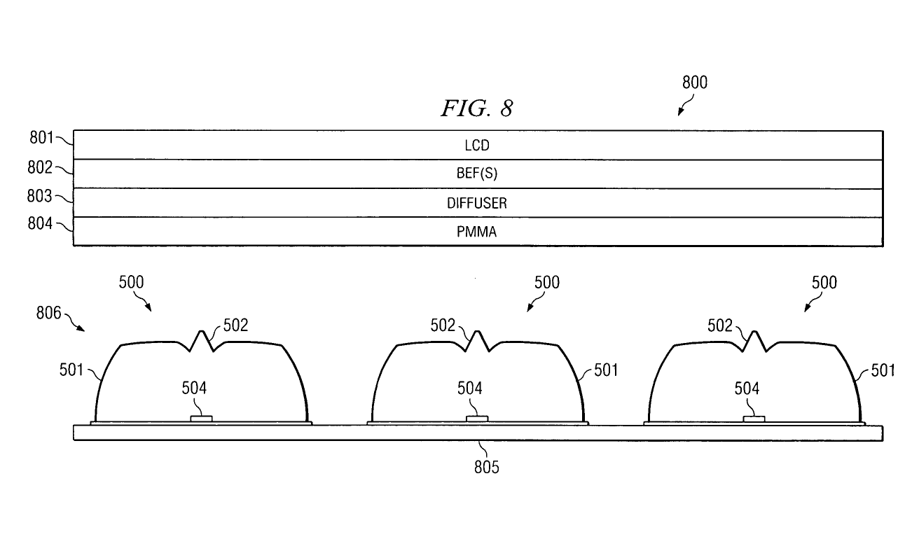

FIG. 8 depicts LCD device 800 according to one representative embodiment. LCD device 800 includes some elements typical of conventional LCDs. For example, LCD device 800 may include LCD panel layer 801 that includes polarizers, liquid crystal material, and electronic control elements. LCD device 800 includes brightness enhancement film (BEF) layer(s) 802 that have light focusing properties. LCD device 800 preferably includes diffuser 803 to achieve greater uniformity in the illumination across LCD device 800. LCD device 800 includes PMMA layer 804 which may be partially reflective. LCD device 800 also includes bottom reflector 805.

LCD device 800 further comprises backlighting module 806 having a plurality of LEDs 500. Each LED 500 includes conical structure 502. Accordingly, LEDs 500 operate as side emission devices and the uniformity of the illumination across LCD device 800 is maintained even when the size of LCD device 800 is increased.

What is claimed is:

1. A light emitting diode (LED) device, comprising:
an LED die for generating output light; and
an encapsulant sealing said LED die, said encapsulant comprising a conical structure extending away from said LED die and positioned above said LED die, wherein a profile of said conical structure causes a cone of light centered around an axis of symmetry of said LED die to experience total internal reflection.

2. The LED device of claim 1 wherein said encapsulant causes said LED device to operate as a side emission device.

3. The LED device of claim 1 wherein said conical structure is disposed within a depression of said encapsulant.

4. The LED device of claim 3 wherein light incident on said depression is refracted away from said axis of symmetry.

5. The LED device of claim 1 wherein said encapsulant comprises multiple layers including a mold cup layer.

6. The LED device of claim 1 wherein said mold cup layer comprises said conical structure.

7. A method of fabricating a light emitting diode (LED) device, comprising:
providing a mold defining an encapsulant profile;
dispensing liquid encapsulant material into said mold;
providing an LED die; and
curing said liquid encapsulant to encapsulate said LED die, wherein said cured encapsulant possesses a conical structure above and extending away from said LED die, wherein a profile of said conical structure causes a cone of light centered around an axis of symmetry of said LED die to experience total internal reflection.

8. The method of claim 7 wherein said dispensing is performed according to injection molding.

9. The method of claim 7 wherein said dispensing is performed according to transfer molding.

10. The method of claim 7 further comprising:
removing said mold after performing said curing.

11. The method of claim 7 wherein said mold is integrated with said cured encapsulant upon completion of said LED device.

12. The method of claim 7 wherein said conical structure is disposed within a depression of said cured encapsulant.

13. The method of claim 12 wherein light incident upon said depression is refracted away from said axis of symmetry.

14. A liquid crystal display (LCD), comprising:
a liquid crystal panel;
a backlighting module for illuminating said liquid crystal panel that comprises a plurality of light emitting diode (LED) devices, wherein each LED device comprises an encapsulant sealing an LED die, said encapsulant comprising a conical structure extending away from said LED die and positioned above said LED die, wherein a profile of said conical structure causes a cone of light centered around an axis of symmetry of said LED die to experience total internal reflection.

15. The LCD of claim 14 wherein said encapsulant causes said LED device to operate as a side emission device.

16. The LCD of claim 14 wherein said conical structure is disposed within a depression of said encapsulant.

17. The LCD of claim 16 wherein light incident on said depression is refracted away from said axis of symmetry.

18. The LCD of claim 14 wherein said encapsulant comprises multiple layers including a mold cup layer.

19. The LCD of claim 14 wherein said mold cup layer comprises said conical structure.

20. The LCD of claim 14 wherein said liquid crystal panel comprises a diffusing layer.
